(19) United States
(12) Patent Application Publication
(10) Pub. No.: US 2015/0147836 A1
(43) Pub. Date: May 28, 2015

(54) COMPOSITION FOR CLEANING FLAT PANEL DISPLAY AND METHOD FOR MANUFACTURING DISPLAY DEVICE USING THE SAME

(71) Applicants: Samsung Display Co., Ltd., Yongin-city (KR); ENF Technology Co., Ltd, Seoul (KR)

(72) Inventors: In-Bae Kim, Yongin-city (KR); Jong-Hyun Choung, Hwaseong-si (KR); Young Min Moon, Seongnam-si (KR); Hong Sick Park, Suwon-si (KR); Hyeon Jeong Sang, Bucheon-si (KR); Jae Woo Jeong, Incheon (KR); Min Hee Kim, Chungcheongnam-do (KR); Young Jin Park, Chungcheongnam-do (KR); Sang-Moon Yun, Chungcheongbuk-do (KR); Sang Dai Lee, Hwaseong-si (KR); Hyun Cheol Jeong, Busan (KR)

(21) Appl. No.: 14/332,215

(22) Filed: Jul. 15, 2014

(30) Foreign Application Priority Data
Nov. 26, 2013 (KR) 10-2013-0144858

(51) Int. Cl. H01L 21/02; H01L 27/15

(52) U.S. Cl. CPC H01L 21/02043; H01L 27/153
USPC 438/34; 510/175

(57) ABSTRACT

The disclosure provides a cleaning agent composition for a flat panel display device, including: polyaminocarboxylic acid; alkali base; a nonionic surfactant; and a fluoride component. The cleaning agent composition for the flat panel display device can effectively remove metal oxides and organic contaminants on the substrate without impairing a transparent conductive layer.

### INCORPORATION BY REFERENCE TO ANY PRIORITY APPLICATIONS

Any and all priority claims identified in the Application Data Sheet, or any correction thereto, are hereby incorporated by reference under 37 CFR 1.57. For example, this application claims priority to and the benefit of Korean Patent Application No. 10-2013-0144858 filed in the Korean Intellectual Property Office on Nov. 26, 2013, the disclosure of which is incorporated herein in its entirety by reference.

### BACKGROUND

1. Field

This disclosure relates to a cleaning agent composition for a flat panel display device, and a manufacturing method using the same.

2. Description of the Related Technology

A flat panel display (FPD) device, such as a liquid crystal display device, may be manufactured by a layer forming process, an exposing process, and an etching process. During manufacture minute particles, such as various types of organic or inorganic materials having sizes of less than 1 μm, may be attached on a surface of a substrate causing contamination.

Removal of contamination is necessary before starting a subsequent process to maintain acceptable yield rate for manufacturing a device.

Thus, cleaning is performed to remove contaminants before starting each process.

A tetramethylammonium hydroxide solution, conventionally used for removing contaminants, removes inorganic particles while being inadequate for removing organic materials, and in particular, causes corrosion on a conductive transparent layer, and removal of iron oxides among metal oxides is unlikely to occur.

Particularly, external iron oxide contamination frequently occurs when moving the substrate from one place to another, and thus a demand for a cleaning agent solution which effectively removes the iron oxides is increasing.

The above information disclosed in this Background section is only for enhancement of understanding of the background of the invention and therefore it may contain information that does not form the prior art that is already known in this country to a person of ordinary skill in the art.

### SUMMARY

Some embodiments provide a cleaning agent composition and a manufacturing method using the same that are suitable for cleaning organic contaminants or particles on a clean substrate, metal oxides, and polished residues generated in polishing a glass substrate.

According to an exemplary embodiment, the cleaning agent composition includes a polyaminocarboxylic acid, a base, a nonionic surfactant, fluoride component, and water. In some embodiments, the fluoride component includes fluoride ions.

In some embodiments, the polyaminocarboxylic acid may be one or more selected from ethylenediaminetetraacetic acid, diethylenetriaminepentaacetic acid, ethyleneglycoltetraacetic acid, hydroxyethylethylenediaminetriacetic acid, ethylenediamine-N,N′-bis(2-hydroxyphenylacetic acid), 1,2-bis(aminophenoxy)ethanetetraacetic acid, 1,4,7,10-tetraazacyclodecane-1,4,7,10-tetraacetic acid, 1,4,8,11-tetraazacyclotetradecane-N,N,N,N-tetraacetic acid, and 1,4,7-triazacyclononane-N,N,N-triacetic acid.

In some embodiments, the amount of the polyaminocarboxylic acid may be 0.1 to 20 wt % with respect to a total weight of the cleaning agent composition.

In some embodiments, the base may be one or more selected from monoethanolamine, diethanolamine, triethanolamine, amino ethoxy ethanol, tetramethyl ammonium hydroxide, tetraethyl ammonium hydroxide, potassium hydroxide, and sodium hydroxide. In some embodiments, the base may be an alkali compound.

In some embodiments, the base may be amount of the base may be 0.1 to 10 wt % with regard to the total weight of the cleaning agent composition.

In some embodiments, the base may be nonionic surfactant may be one or more selected from aromatic or aliphatic oxyethylene-oxypropylene, an oxyethylene-oxypropylene copolymer, and alkyl polyglucoside with an alkyl radical including 1 to 4 carbon atoms.

In some embodiments, the base may be amount of the nonionic surfactant may be 0.001 to 20 wt % with regard to the total weight of the cleaning agent composition.

In some embodiments, the base may be fluoride component may be one or more among hydrogen fluoride, ammonium fluoride, ammonium bifluoride, potassium fluoride, potassium bifluoride, and fluoboric acid fluoborate.

In some embodiments, the base may be amount of the fluoride component may be 0.001 to 20 wt % with regard to the total weight of the cleaning agent composition.

In some embodiments, the base may be cleaning agent composition may further include an alcoholic organic solvent.

In some embodiments, the base may be alcoholic organic solvent may be one or more among ethanol, propanol, butanol, hexanol, heptanol, octanol, decanol, isopropanol, isohexanol, isooctanol, isodecanol, ethylene glycol, diethylene glycol, triethylene glycol, ethylene glycol methyl ether, diethylene glycol methyl ether, triethylene glycol methyl ether, ethylene glycol ethyl ether, diethylene glycol ethyl ether, triethylene glycol ethyl ether, ethylene glycol monopropyl ether, diethylene glycol monopropyl ether, triethylene glycol monopropyl ether, ethylene glycol monobutyl ether, diethylene glycol monobutyl ether, triethylene glycol monobutyl ether, ethylene glycol dibutyl ether, diethylene glycol dibutyl ether, triethylene glycol dibutyl ether, ethylene glycol monohexyl ether, diethylene glycol monohexyl ether, and triethylene glycol monohexyl ether.

In some embodiments, the base may be amount of the organic solvent may be 0.01 to 20 wt % with regard to the total weight of the cleaning agent composition.

In addition, a manufacturing method of a display device according to an exemplary embodiment includes: cleaning an insulation substrate by using a cleaning agent solution containing a cleaning agent composition; forming a gate metal layer on the insulation substrate; forming gate lines including a gate electrode by etching the gate metal layer; forming a gate insulation layer on the gate lines; sequentially forming an amorphous silicon layer, an amorphous silicon layer doped with impurities, and a data metal layer; forming a semiconductor, ohmic contacts, data lines including a source electrode, and a drain electrode by etching the amorphous silicon layer, the amorphous silicon layer doped with impurities, and the data metal layer; forming a passivation layer on the data lines, the drain electrode, and the gate insulation layer; and forming a pixel electrode on the passivation layer. The cleaning agent composition includes 0.1 to 10 wt % of the polyaminocarboxylic acid, 0.1 to 10 wt % of the alkali, 0.001 to 20 wt % of the nonionic surfactant, 0.001 to 20 wt % of the fluoride ions, and water, with regard to the total weight of the cleaning agent composition.

As described above, the cleaning agent composition for the flat panel display device according to the exemplary embodiment can effectively remove metal oxides and organic contaminants on the substrate without impairing a transparent conductive layer.

### BRIEF DESCRIPTION OF THE DRAWINGS

FIG. 1 provides experimental results showing degrees of contaminant removal when a cleaning agent composition according to an exemplary embodiment and a conventional cleaning agent composition are used.

FIG. 2 is a graph showing contaminant reduction rates on a substrate when the cleaning agent composition according to the exemplary embodiment and a conventional cleaning agent composition are used.

FIG. 3A shows a substrate after it is cleaned by using a cleaning agent composition according to a first exemplary embodiment.

FIG. 3B shows a substrate after it is cleaned by using a cleaning agent composition according to a second exemplary embodiment.

FIG. 3C shows a substrate after it is cleaned by using a cleaning agent composition according to a fourth exemplary embodiment.

FIG. 3D shows a substrate after it is cleaned by using a cleaning agent composition according to Comparative Example 3.

FIG. 3E shows a substrate after it is cleaned by using a cleaning agent composition according to Comparative Example 4.

FIG. 4 is a layout view of a thin film transistor array panel according to an exemplary embodiment.

FIG. 5 is a cross-sectional view of FIG. 4 taken along the line II-II.

FIGS. 6 to 12 are cross-sectional views sequentially showing a manufacturing method of a thin film transistor array panel for a display device according to an exemplary embodiment.

### DETAILED DESCRIPTION

The present disclosure will be described more fully hereinafter with reference to the accompanying drawings, in which exemplary embodiments are shown.

As those skilled in the art would realize, the described embodiments may be modified in various different ways, all without departing from the spirit or scope of the present embodiments.

In the drawings, the thickness of layers, films, panels, regions, etc., are exaggerated for clarity.

Like reference numerals designate like elements throughout the specification.

It will be understood that when an element such as a layer, film, region, or substrate is referred to as being “on” another element, it can be directly on the other element or intervening elements may also be present.

In contrast, when an element is referred to as being “directly on” another element, there are no intervening elements present.

Now, a cleaning agent composition for a flat panel display device according to an exemplary embodiment will be described in detail.

The cleaning agent composition for the flat panel display device according to the exemplary embodiment may be used to remove contaminants on a substrate for the display device.

Among metal oxides as externally inflowing materials, iron oxide (rust) is generally attached to the substrate to cause corrosion on iron structures in a workplace while delivering glass from one place to another, thereby frequently contaminating the substrate.

Once these iron oxides are attached to the substrate, they are difficult to remove by conventional acid or alkali cleaning agents.

In some embodiments, the cleaning agent composition includes a polyaminocarboxylic acid, alkali base, a nonionic surfactant, fluoride component, and residual water. In some embodiments, the fluoride component includes fluoride ions.

The polyaminocarboxylic acid is a major component for selectively removing the metal oxides by having six or more sites to be combined with metal ions such that they can be eliminated from the substrate by reacting with the metal oxides particles.

In addition, the polyaminocarboxylic acid has low reactivity with a transparent conductive layer forming the substrate such that it does not cause corrosion.

In some embodiments, the polyaminocarboxylic acid is one or more selected from ethylenediaminetetraacetic acid, diethylenetriaminepentaacetic acid, ethyleneglycoltetraacetic acid, hydroxyethylethylenediaminetriacetic acid, ethylenediamine-N,N′-bis(2-hydroxyphenylacetic acid), 1,2-bis(aminophenoxy) ethanetetraacetic acid, 1,4,7,10-tetraazacyclodecane-1,4,7,10-tetraacetic acid, 1,4,8,11-tetraazacyclotetradecane-N,N,N,N-tetraacetic acid, and 1,4,7-triazacyclononane-N,N,N-triacetic acid.

In some embodiments, the amount of the polyaminocarboxylic acid may be 0.1 to 20 wt % with respect to the total weight of the cleaning agent composition.

In some embodiments, the base may be an organic or inorganic base.

In some embodiments, the organic or inorganic base may be one or more selected from monoethanolamine, diethanolamine, triethanolamine, amino ethoxy ethanol, tetramethyl ammonium hydroxide, tetraethyl ammonium hydroxide, potassium hydroxide, and sodium hydroxide.

In some embodiments, the amount of base may be 0.1 to 10 wt % with regard to the total weight of the cleaning agent composition.

The nonionic surfactant has a low-foaming property, enhances cleaning power, and serves to solubilize components of the cleaning agent composition that are difficult to dissolve.

In some embodiments, the nonionic surfactant having the low-foaming property may be one or more selected from an aromatic or aliphatic oxyethylene-oxypropylene, oxyethylene-oxypropylene copolymer, and alkyl polyglucoside with an alkyl radical comprising 1 to 4 carbon atoms.

In some embodiments, the amount of the nonionic surfactant may be 0.001 to 20 wt % with regard to the total weight of the cleaning agent composition. In some embodiments, the amount of the nonionic surfactant may be 0.01 to 5 wt % with regard to the total weight of the cleaning agent composition.

The cleaning agent composition provides insufficient cleaning power when the amount of the nonionic surfactant is less than 0.01 wt %, and phase stability is not achieved when the amount of the nonionic surfactant exceeds 20 wt %.

In some embodiments, the fluoride component may provide fluoride ions which weaken points of attachment between the substrate and the inorganic contaminant particles by minutely etching the substrate, thereby enhancing the cleaning power against the contaminants on the substrate.

In some embodiments, the fluoride component may be one or more among hydrogen fluoride, hydrogen fluoride, ammonium bifluoride, potassium fluoride, potassium bifluoride, and fluoboric acid fluoborate.

In some embodiments, the amount of the fluoride component may be 0.001 to 20 wt % with regard to the total weight of the cleaning agent composition. In some embodiments, the amount of the fluoride ion may be 0.01 to 1 wt % with regard to the total weight of the cleaning agent composition.

In addition, a cleaning agent composition according to another exemplary embodiment may further include an alcoholic organic solvent.

The alcoholic organic solvent serves to enhance the cleaning power against oil based contaminants, and solubilizes the components of the cleaning agent composition that is difficult to dissolve in water.

In some embodiments, the alcoholic organic solvent may be one or more among ethanol, propanol, butanol, hexanol, heptanol, octanol, decanol, isopropanol, isohexanol, isooctanol, isodecanol, ethylene glycol, diethylene glycol, triethylene glycol, ethylene glycol methyl ether, diethylene glycol methyl ether, triethylene glycol methyl ether, ethylene glycol ethyl ether, diethylene glycol ethyl ether, triethylene glycol ethyl ether, ethylene glycol monopropyl ether, diethylene glycol monopropyl ether, triethylene glycol monopropyl ether, ethylene glycol monobutyl ether, diethylene glycol monobutyl ether, triethylene glycol monobutyl ether, ethylene glycol dibutyl ether, diethylene glycol dibutyl ether, triethylene glycol dibutyl ether, ethylene glycol monohexyl ether, diethylene glycol monohexyl ether, and triethylene glycol monohexyl ether, but it is not limited thereto.

In some embodiments, the amount of the alcoholic organic solvent may be 0.01 to 20 wt % with regard to the total weight of the cleaning agent composition. In some embodiments, the amount of the alcoholic organic solvent may be 1 to 20 wt % with regard to the total weight of the cleaning agent composition.

The water is deionized water for processing semiconductors, and an resistivity of water exceeding 18 mΩ/cm may be consumed.

The cleaning agent composition according to the exemplary embodiment may further include a conventional additive in addition to the above-described elements.

By using the cleaning agent composition for the flat panel display device according to the exemplary embodiment, the metal oxides and organic contaminants on the substrate may be effectively removed without impairing the transparent conductive layer.

A manufacturing method using the cleaning agent composition according to the exemplary embodiment will be described hereinafter.

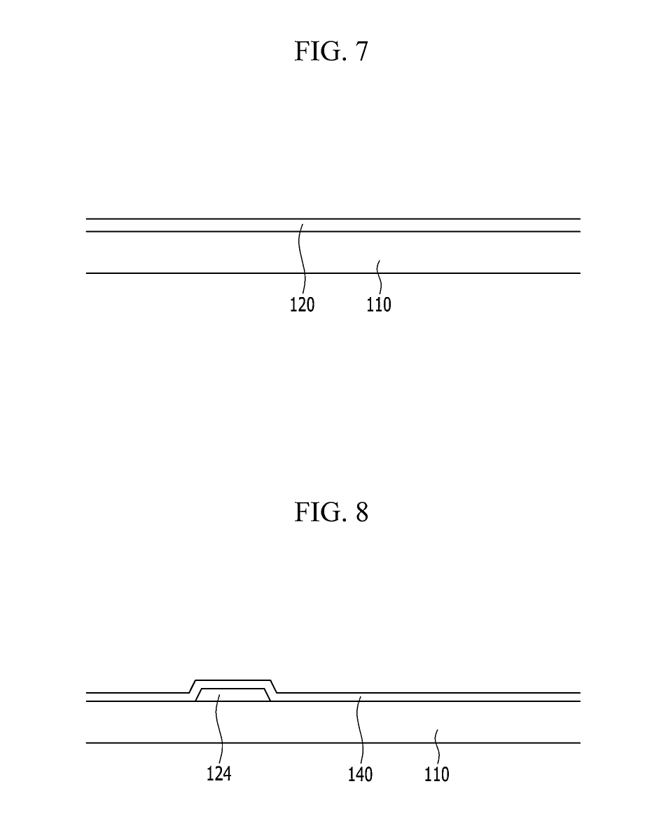

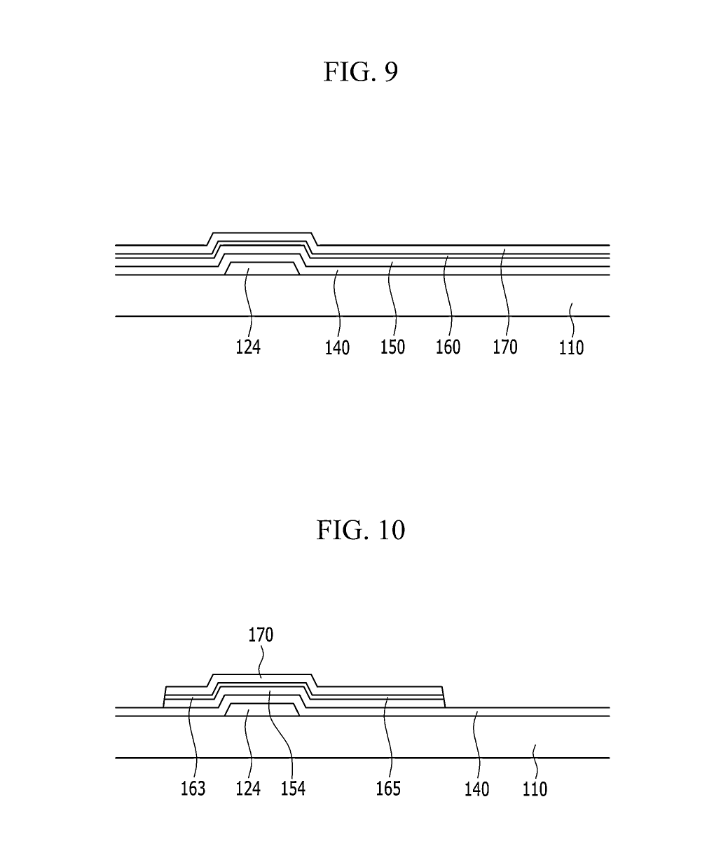

FIG. 4 is a layout view of a thin film transistor array panel according to the exemplary embodiment, and FIG. 5 is a cross-sectional view of FIG. 4 taken along the line II-II.

A thin film transistor array panel for the display panel according to the exemplary embodiment may be sequentially formed with a plurality of gate lines 121 including a gate electrode 124 on a substrate 110 formed of transparent glass or plastic, a gate insulation layer 140, a plurality of semiconductor layers 154, a plurality of ohmic contacts 163 and 165, a plurality of data lines 171, and a plurality of drain electrodes 175.

In some embodiments, the gate lines 121 transmit gate signals and mainly extend in a horizontal direction, and the gate electrode 124 protrudes above the gate lines 121.

In some embodiments, the data lines 171 transmit data signals and mainly extend in a vertical direction to cross the gate lines 121.

Each of the data lines 171 includes a plurality of source electrodes 173 which extend towards the gate electrode 124.

In some embodiments, the drain electrode 175 is separated from the data lines 171, and faces the source electrode 173 based on the gate electrodes 124.

In some embodiments, the semiconductor layer 154 is disposed above the gate electrode 124, and the ohmic contacts 163 and 165 are disposed only between the semiconductor layer 154 and the data lines 171 and the semiconductor layer 154 and the drain electrode 175 to reduce contact resistances therebetween.

One gate electrode 124, one source electrode 173, and one drain electrode 175 form one thin film transistor (TFT) together with the semiconductor layer 154, and a channel of the thin film transistor is formed in the semiconductor layer 154 between the source electrode 173 and the drain electrode 175.

A passivation layer 180 made of a silicon nitride or a silicon oxide is formed on the data line 171 and the drain electrode 175.

A contact hole 185 is formed to expose the drain electrode 175 in the passivation layer 180, and a pixel electrode 191 is formed on the passivation layer 191 to be connected to the drain electrode 175 through the contact hole 185.

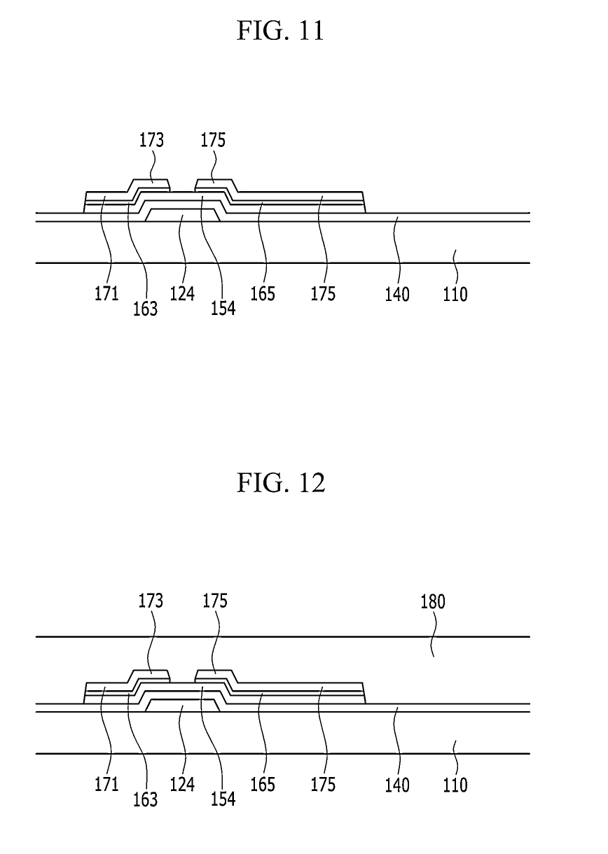

Now, a manufacturing method of a thin film transistor array panel for a display device according to an exemplary embodiment of the present invention will be described with reference to FIG. 5 together with FIGS. 6 to 12.

FIGS. 6 to 12 are cross-sectional views sequentially showing the manufacturing method of the thin film transistor array panel for the display device according to an exemplary embodiment.

First, a transparent insulation substrate 110 in FIG. 6 is cleaned by using a cleaning solution including a cleaning agent composition according to the exemplary embodiment.

Next, as shown in FIG. 7, a gate metal layer 120 is formed on the transparent insulation substrate 110.

Next, as shown in FIG. 8, the gate metal layer 120 is etched by using an etching solution for the gate metal layer 120 to form a gate electrode 124, and a gate insulation layer 140 is formed on an entire surface of the insulation substrate including the gate electrode 124.

Next, as shown in FIG. 9, the gate insulation layer 140 is sequentially laminated with an amorphous silicon layer 150, an amorphous silicon layer 160 doped with impurities, and a data metal layer 170.

Next, as shown in FIGS. 10 and 11, the data metal layer 170 is etched by using an etching solution therefor, and the amorphous silicon layer 150 and amorphous silicon layer 160 doped with impurities are etched to form a data line 171 including a source electrode 173, a drain electrode 175, ohmic contacts 163 and 165, and a semiconductor layer 154.

Next, as shown in FIG. 12, after a passivation layer 180 is formed on the entire surface of the data line 171, the drain electrode 175, and the gate insulation layer 140, a contact hole 185 is formed to expose the drain electrode 175 as shown in FIG. 4, and a pixel electrode 191 is formed on the passivation layer 180.

Hereinafter, although preferable exemplary embodiments are provided for easier understanding of the present embodiments, the following exemplary embodiments are provided merely to illustrate the present embodiments, but the scope of the present embodiments is not limited to the following exemplary embodiments.

Cleaning agent compositions according to Exemplary Embodiments 1 to 5 and Comparative Examples 1 to 4 are manufactured by mixing and agitating according to the components and compositions (wt %) written in Table 1 below.

TABLE 1

| | Exemp. | Exemp. | Exemp. | Exemp. | Exemp. | Comp. | Comp. | Comp. | Comp. |
|---|---|---|---|---|---|---|---|---|---|
| | Embod. 1 | Embod. 2 | Embod. 3 | Embod. 4 | Embod. 5 | Ex. 1 | Ex. 2 | Ex. 3 | Ex. 4 |
| KOH | 4 | 4 | 4 | 4 | 4 | 4 | 4 | | 4 |
| IDA | | | | | | 8 | | | |
| NTA | | | | | | | 8 | | |
| DPTA | 8 | | | 8 | 8 | | | 8 | 8 |
| EGTA | | 8 | 8 | | | | | | |
| BDG | 5 | 5 | 5 | | | 5 | 5 | 5 | 5 |
| APEP141 | 2 | 2 | | 2 | 2 | 2 | 2 | 2 | |
| EPE | | | 2 | | | | | | |
| AF | 0.5 | 0.5 | 0.5 | 0.5 | | | | | |
| DIW | 80.5 | 80.5 | 80.5 | 85.5 | 85.5 | 81 | 81 | 85 | 83 |

KOH: potassium hydroxide
IDA: imminodiacetic acid
NTA: nitrilotriacetic acid
DTPA: diethylenetriaminepentaacetic acid
EGTA: ethylene glycol tetraacetic acid
BDG: diethylene glycol monobutyl ether
APEP 141: fatty alcohol ethoxylate
EPE: oxyethylene-oxypropylene copolymer
AF: ammonium fluoride
DIW: deionized water

### Experimental Example 1

### Contaminant Removal Evaluation for Iron Oxide

An iron oxide contaminant used for evaluating cleaning power is prepared as follows. A rusted nail is soaked in deionized water to get iron dust by using ultrasonic waves, and a 50 mm×50 mm LCD glass substrate is sprayed with a contamination source including the iron dust and is then vacuum-dried (at 1 Torr) for a day in order to get a specimen.

The prepared specimen is cleaned with an ultrasonic cleaner (44 kHz, 40° C.) by using the cleaning solutions in which the cleaning agent compositions according to Exemplary Embodiments 1 to 5 and Comparative Examples 1 to 2 are 20-fold diluted by deionized water.

After 60 seconds, the cleaned specimen is viewed through an optical microscope to evaluate a surface status and degrees of removal.

The results are shown in Table 2 below.

In Table 2 below showing the results of the surface status and the degree of removal for iron oxide, ⊚ stands for excellent, ∘ for very good, Δ for good, and x for bad.

TABLE 2

| | Degree of contaminant removal | |
|---|---|---|
| Cleaning agent composition | after 30 seconds | after 60 seconds |
| Exemplary Embodiment 1 | ⊚ | ⊚ |
| Exemplary Embodiment 2 | ⊚ | ⊚ |
| Exemplary Embodiment 3 | ⊚ | ⊚ |
| Exemplary Embodiment 4 | ◯ | ⊚ |
| Exemplary Embodiment 5 | Δ | ◯ |
| Comparative Example 1 | X | X |
| Comparative Example 2 | X | X |

As shown in Table 2, excellent cleaning power is achieved when the cleaning agent compositions according to Exemplary Embodiments 1 to 5 of the present disclosure are used, while the cleaning power against iron oxide is insufficient when the conventional aminopolycarboxylic acid is used according to Comparative Example 1 and 2.

The cleaning power of the cleaning agent composition according to exemplary embodiments of the present disclosure is further enhanced by minutely etching a surface of the glass substrate with a small amount of the fluoride ions.

### Experimental Example 2

### Contaminant Removal Evaluation for Oily Soil

Oily soil contaminant used for evaluating cleaning power is prepared as follows. A 50 mm×50 mm LCD glass substrate is coated with soybean oil, tallow, oil red (dye), and chloroform (solvent) in respective quantities of 10 g, 10 g, 0.1 g, and 60 mL by using a spin coater, and is then vacuum-dried (under 1 Torr) for one minute to get a specimen.

The prepared specimen is cleaned with an ultrasonic cleaner (44 kHz, 40° C.) by using the cleaning solutions in which the cleaning agent compositions according to Exemplary Embodiments 1 to 5 and Comparative Examples 3 to 4 are 20-fold diluted with deionized water.

After 60 seconds, the cleaned specimen is viewed through an optical microscope with a contact angle analyzer to evaluate a surface status and degrees of contaminant removal.

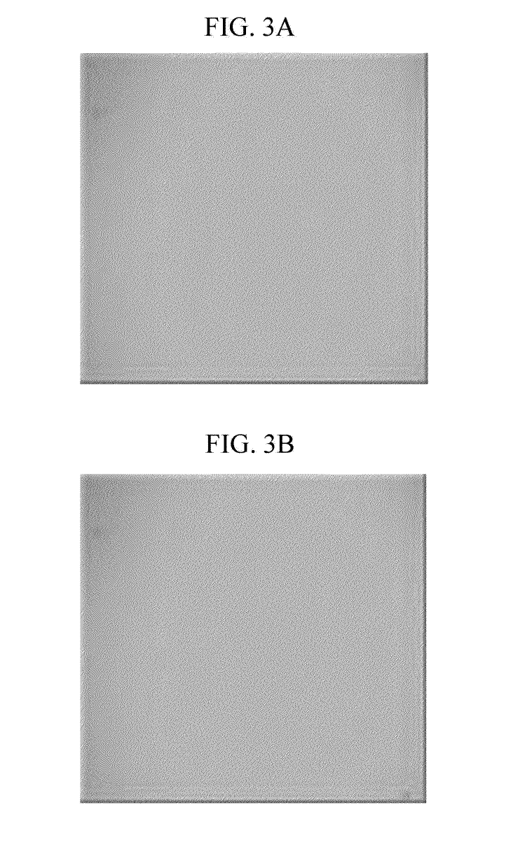

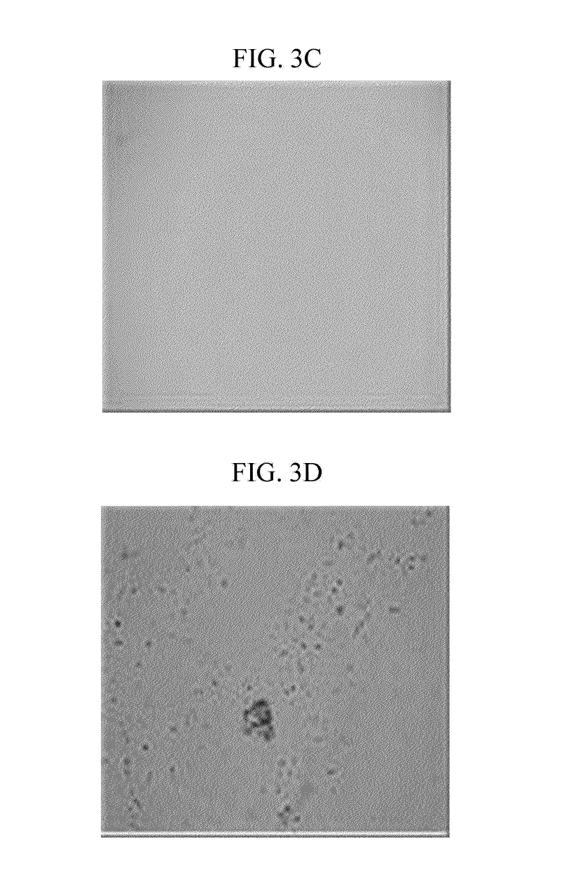

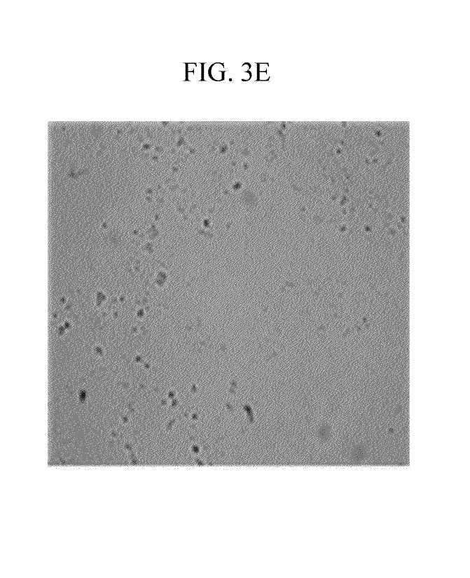

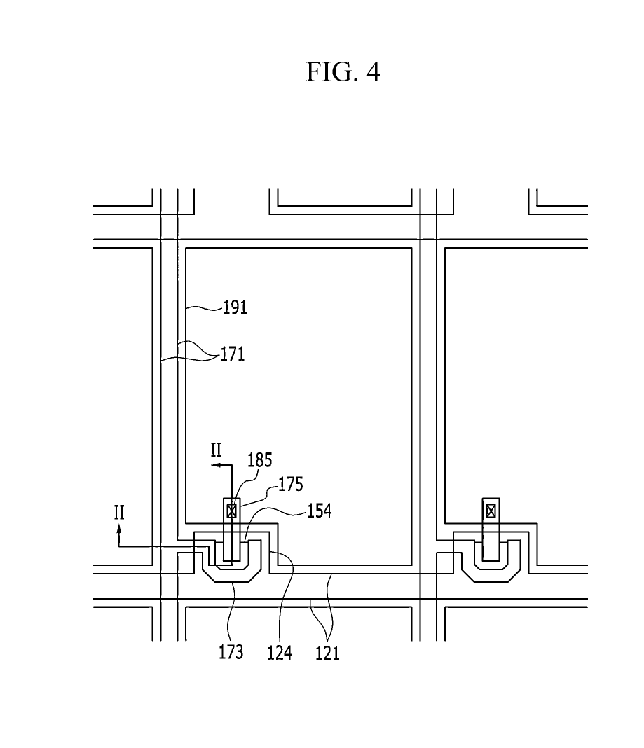

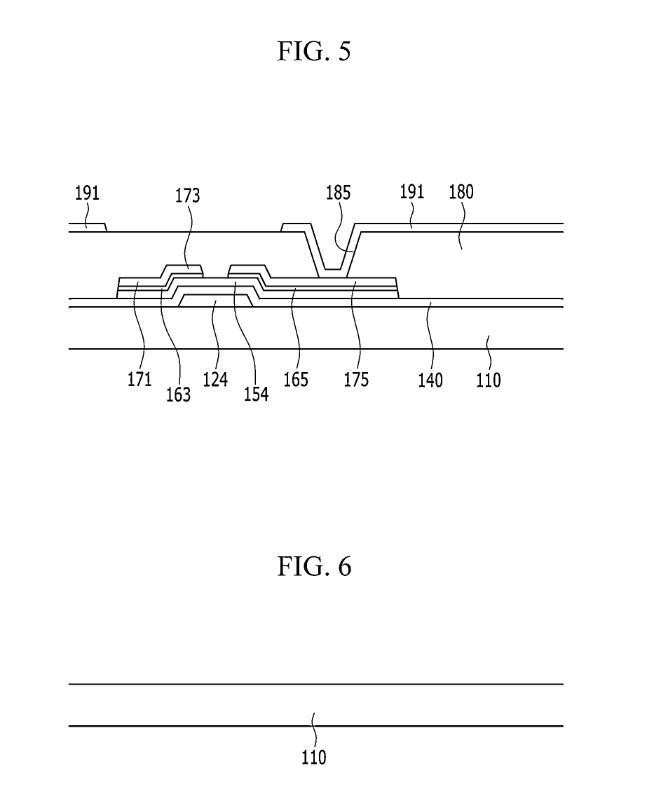

The results are shown in FIG. 3 and Table 3.

In Table 3 below showing the results of the surface status and the degree of removal, ⊚ stands for excellent, ∘ for very good, Δ for good, and x for bad.

TABLE 3

| | Degrees of contaminant removal | | | |
|---|---|---|---|---|
| | and contact angle (°) | | | |
| Cleaning agent composition | After 30 seconds | | After 60 seconds | |
| Exemplary Embodiment 1 | ⊚ | 28 | ⊚ | 27 |
| Exemplary Embodiment 2 | ⊚ | 28 | ⊚ | 26 |
| Exemplary Embodiment 3 | ◯ | 32 | ⊚ | 27 |
| Exemplary Embodiment 4 | ◯ | 35 | ⊚ | 29 |
| Exemplary Embodiment 5 | ◯ | 34 | ⊚ | 29 |
| Comparative Example 3 | X | 54 | X | 53 |
| Comparative Example 4 | X | 56 | X | 55 |

As shown in FIG. 3 and Table 3, excellent cleaning power is achieved when the cleaning agent compositions according to the Exemplary Embodiments 1 to 4 are used, but the cleaning power is decreased when the cleaning agent compositions of Comparative Examples 3 and 4 without an organic base or surfactant are used.

### Experimental Example 3

### Anticorrosive Property Evaluation for ITO Thin Film

An LCD glass substrate deposited with 20 mm×40 mm ITO is dipped into the cleaning solutions of Exemplary Embodiments 1 to 5, Comparative Examples 1 and 2, and Comparative Example 4 in which the cleaning agent compositions are 20-fold diluted with deionized water while being maintained at a temperature of 40° C., and its surface resistance is measured to evaluate respective anticorrosive properties of corrosion inhibitors.

The results are shown in Table 4 below.

TABLE 4

| Cleaning agent composition | Corrosion rate Å/min |
|---|---|
| Exemplary Embodiment 1 | 0.5 |
| Exemplary Embodiment 2 | 0.4 |
| Exemplary Embodiment 3 | 0.6 |
| Exemplary Embodiment 4 | 0.9 |
| Exemplary Embodiment 5 | 0.8 |
| Comparative Example 1 | 75.4 |
| Comparative Example 2 | 54.2 |
| Comparative Example 4 | 0.7 |

As shown in Table 4, corrosion rates are very low when the polyaminopolycarboxylic acid is used as in Exemplary Embodiments 1 to 5, while corrosion rates are increased when the aminopolycarboxylic acid is used as in Comparative Examples 1 and 2.

### Experimental Example 4

### Comparative Evaluation of 0.4% TMAH (Tetra Methyl Ammonium Hydroxide)

The glass substrate is contaminated according to the procedure disclosed in Experimental Example 1 to 2, and is then cleaned with the ultrasonic cleaner (44 kHz, 40° C.) by using 0.4% TMAH (tetra methyl ammonium hydroxide) and the cleaning solution in which the cleaning agent composition of the exemplary embodiment 1 is 20-fold diluted with deionized water.

After 60 seconds, the cleaned specimen is viewed through an optical microscope to evaluate degrees of removal and a cleaning completion time.

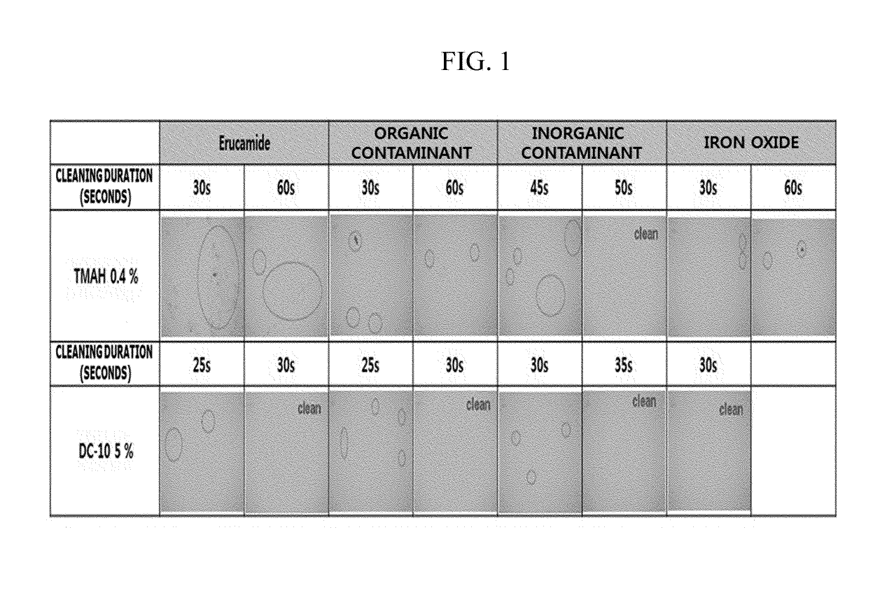

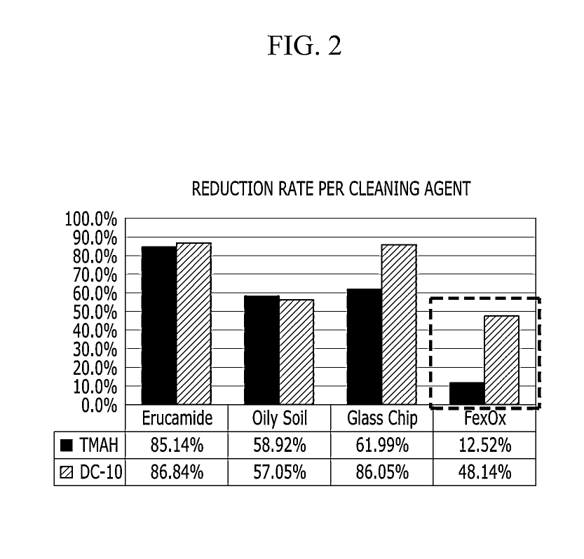

The results are shown in FIGS. 1 to 2 and Tables 5 to 7 below.

TABLE 5

| | | Organic | Inorganic | |
|---|---|---|---|---|
| | Erucamide | contaminant | contaminant | Iron oxide |
| TMAH | X | X | 50 seconds | X |
| Exemplary | 30 seconds | 30 seconds | 35 seconds | 30 seconds |
| Embodiment 1 | | | | |

TABLE 6

| | TMAH | | | |
|---|---|---|---|---|
| | | After cleaning | | |
| | Before cleaning | | No. of | |
| | No. of | No. of | reduced | Reduction |
| Contaminant | particles | particles | particles | rate |
| Erucamide | 5300 | 787.5 | 4512.5 | 85.14% |
| Organic contaminant | 2100 | 862.75 | 1237.25 | 58.92% |
| Inorganic contaminant | 8800 | 3344.5 | 5455.5 | 61.99% |
| Iron oxide | 900 | 787.5 | 112.5 | 12.52% |

TABLE 7

| | Exemplary Embod. 1 | | | |
|---|---|---|---|---|
| | | After cleaning | | |
| | Before cleaning | | No. of | |
| | No. of | No. of | reduced | Reduction |
| Contaminant | particles | particles | particles | rate |
| Erucamide | 5300 | 694 | 4512.5 | 86.84% |
| Organic contaminant | 2100 | 993.5 | 1106.5 | 57.05% |
| Inorganic Contaminant | 8800 | 1541.75 | 7258.25 | 86.05% |
| Iron oxide | 900 | 466.75 | 433.25 | 48.14% |

As shown in FIGS. 1 and 2 and Tables 5 to 7, cleaning power against all types of contaminants is superior and contaminant removal time is short when the cleaning agent composition according to Exemplary Embodiment 1 is used.

Particularly, in case of Exemplary Embodiment 1, the cleaning power against the iron oxide is superior compared with the conventional cleaning solution of 0.4% TMAH.

As describe above, the cleaning agent composition for the flat panel display device may effectively remove the metal oxides and organic contaminants on the substrate for the flat panel display device without impairing the transparent conductive layer.

While the embodiments have been described in connection with what is presently considered to be practical exemplary embodiments, it is to be understood that the embodiments are not limited to the disclosed embodiments and is intended to cover various modifications and equivalent arrangements included within the spirit and scope of the appended claims.

What is claimed is:

1. A cleaning agent composition for a flat panel display device, comprising:
a polyaminocarboxylic acid;
a base;
a nonionic surfactant;
fluoride component; and
water.

2. The composition of claim 1, wherein:
the polyaminocarboxylic acid is one or more selected from ethylenediaminetetraacetic acid, diethylenetriaminepentaacetic acid, ethylene glycoltetraacetic acid, hydroxyethylethylenediaminetriacetic acid, ethylenediamine-N,N′-bis(2-hydroxyphenylacetic acid), 1,2-bis(aminophenoxy) ethanetetraacetic acid, 1,4,7,10-tetraazacyclodecane-1,4,7,10-tetraacetic acid, 1,4,8,11-tetraazacyclotetradecane-N,N,N,N-tetraacetic acid, and 1,4,7-triazacyclononane-N,N,N-triacetic acid.

3. The composition of claim 2, wherein:
the amount of the polyaminocarboxylic acid is 0.1 to 20 wt % with respect to the total weight of the cleaning agent composition.

4. The composition of claim 1, wherein:
the base is one or more selected from monoethanolamine, diethanolamine, triethanolamine, amino ethoxy ethanol, tetramethyl ammonium hydroxide, tetraethyl ammonium hydroxide, potassium hydroxide, and sodium hydroxide.

5. The alkali of claim 4, wherein:
the amount of the base is 0.1 to 10 wt % with regard to the total weight of the cleaning agent composition.

6. The composition of claim 1, wherein:
the nonionic surfactant is one or more selected from aromatic or aliphatic oxyethylene-oxypropylene, an oxyethylene-oxypropylene copolymer, and alkyl polyglucoside with an alkyl radical comprising 1 to 4 carbon atoms.

7. The composition of claim 6, wherein:
the amount of the nonionic surfactant is 0.001 to 20 wt % with regard to the total weight of the cleaning agent composition.

8. The composition of claim 1, wherein:
the fluoride component is one or more selected from hydrogen fluoride, ammonium fluoride, ammonium bifluoride, potassium fluoride, potassium bifluoride, and fluoboric acid fluoborate.

9. The composition of claim 8, wherein:
the amount of the fluoride component is 0.001 to 20 wt % with regard to the total weight of the cleaning agent composition.

10. The composition of claim 1, wherein:
the amount of the polyaminocarboxylic acid is 0.1 to 10 wt %,
the amount of the alkali is 0.1 to 10 wt %,
the amount of the nonionic surfactant is 0.001 to 20 wt %, and
the amount of the fluoride component is 0.0011 to 20 wt %, with regard to the total of the cleaning agent composition.

11. The composition of claim 1, wherein:
the cleaning agent composition further includes an alcoholic organic solvent.

12. The composition of claim 11, wherein:
the alcoholic organic solvent is one or more among ethanol, propanol, butanol, hexanol, heptanol, octanol, decanol, isopropanol, isohexanol, isooctanol, isodecanol, ethylene glycol, diethylene glycol, triethylene glycol, ethylene glycol methyl ether, diethylene glycol methyl ether, triethylene glycol methyl ether, ethylene glycol ethyl ether, diethylene glycol ethyl ether, triethylene glycol ethyl ether, ethylene glycol monopropyl ether, diethylene glycol monopropyl ether, triethylene glycol monopropyl ether, ethylene glycol monobutyl ether, diethylene glycol monobutyl ether, triethylene glycol monobutyl ether, ethylene glycol dibutyl ether, diethylene glycol dibutyl ether, triethylene glycol dibutyl ether, ethylene glycol monohexyl ether, diethylene glycol monohexyl ether, and triethylene glycol monohexyl ether.

13. The composition of claim 12, wherein:
the amount of the organic solvent is 0.01 to 20 wt % with regard to the total weight of the cleaning agent composition.

14. A manufacturing method of a display device, comprising:
cleaning an insulation substrate by using a cleaning agent solution containing a cleaning agent composition;
forming a thin film transistor including a gate electrode, a semiconductor layer, and source and drain electrodes on the insulation substrate;
forming a passivation layer on the thin film transistor; and
forming a pixel electrode, which is connected to the drain electrode, on the passivation layer, wherein the cleaning agent composition comprises:
0.1 to 10 wt % of a polyaminocarboxylic acid;
0.1 to 10 wt % of alkali base;
0.001 to 20 wt % of a nonionic surfactant;
0.001 to 20 wt % of fluoride component; and
water, with regard to the total weight of the cleaning agent composition.

15. The method of claim 14, wherein:
the polyaminocarboxylic acid is one or more selected from ethylenediaminetetraacetic acid, diethylenetriaminepentaacetic acid, ethyleneglycoltetraacetic acid, hydroxyethylethylenediaminetriacetic acid, ethylenediamine-N,N′-bis(2-hydroxyphenylacetic acid), 1,2-bis(aminophenoxy)ethanetetraacetic acid, 1,4,7,10-tetraazacyclodecane-1,4,7,10-tetraacetic acid, 1,4,8,11-tetraazacyclotetradecane-N,N,N,N-tetraacetic acid, and 1,4,7-triazacyclononane-N,N,N-triacetic acid.

16. The method of claim 14, wherein:
the base is one or more selected from monoethanolamine, diethanolamine, triethanolamine, amino ethoxy ethanol, tetramethyl ammonium hydroxide, tetraethyl ammonium hydroxide, potassium hydroxide, and sodium hydroxide.

17. The method of claim 14, wherein:
the nonionic surfactant is one or more selected from aromatic or aliphatic oxyethylene-oxypropylene, an oxyethylene-oxypropylene copolymer, and alkyl polyglucoside with an alkyl radical comprising 1 to 4 carbon atoms.

18. The method of claim 14, wherein:
the fluoride component is one or more selected from hydrogen fluoride, ammonium fluoride, ammonium bifluoride, potassium fluoride, potassium bifluoride, and fluoboric acid fluoborate.

19. The method of claim 14, wherein:
the cleaning agent composition further comprises 0.01 to 20 wt % of an alcoholic organic solvent with respect to its total weight.

20. The method of claim 19, wherein:
the alcoholic organic solvent is one or more among ethanol, propanol, butanol, hexanol, heptanol, octanol, decanol, isopropanol, isohexanol, isooctanol, isodecanol, ethylene glycol, diethylene glycol, triethylene glycol, ethylene glycol methyl ether, diethylene glycol methyl ether, triethylene glycol methyl ether, ethylene glycol ethyl ether, diethylene glycol ethyl ether, triethylene glycol ethyl ether, ethylene glycol monopropyl ether, diethylene glycol monopropyl ether, triethylene glycol monopropyl ether, ethylene glycol monobutyl ether, diethylene glycol monobutyl ether, triethylene glycol monobutyl ether, ethylene glycol dibutyl ether, diethylene glycol dibutyl ether, triethylene glycol dibutyl ether, ethylene glycol monohexyl ether, diethylene glycol monohexyl ether, and triethylene glycol monohexyl ether.
